(19) United States
(12) Patent Application Publication
(10) Pub. No.: US 2011/0159692 A1
(43) Pub. Date: Jun. 30, 2011

(54) METHOD FOR FABRICATING SEMICONDUCTOR DEVICE

(76) Inventors: Won-Kyu Kim, Gyeonggi-do (KR); Tae-Woo Jung, Gyeonggi-do (KR); Chang-Hee Shin, Gyeonggi-do (KR)

(21) Appl. No.: 12/774,610

(22) Filed: May 5, 2010

(30) Foreign Application Priority Data
Dec. 29, 2009 (KR) 10-2009-0133389

(51) Int. Cl. H01L 21/475

(52) U.S. Cl. 438/697; 257/E21.46; 257/E21.488

(57) ABSTRACT

A method for fabricating semiconductor device includes forming a nitride pattern and a hard mask pattern over a substrate, forming a trench by etching the substrate using the hard mask pattern as an etch barrier, forming an oxide layer filling the trench, performing a planarization process on the oxide layer until the nitride pattern is exposed, and removing the nitride pattern though a dry strip process using a plasma.

### CROSS-REFERENCE TO RELATED APPLICATIONS

The present application claims priority of Korean Patent Application No. 10-2009-0133389, filed on Dec. 29, 2009, which is incorporated herein by reference in its entirety.

### BACKGROUND OF THE INVENTION

Exemplary embodiments of the present invention relate to a semiconductor fabricating technology, and more particularly, to a method for fabricating an isolation structure in a semiconductor device.

When a device isolation layer is formed, a nitride layer is used as a hard mask. After the device isolation layer is formed, a wet strip process is performed to remove the hard mask by using a phosphoric acid (H₃PO₄).

Meanwhile, as semiconductor devices become smaller, isolation materials used for forming device isolation layers are being changed from those formed by using a high density plasma (HDP) process or a boron phosphorus silicate glass (BPSG) to a spin on dielectric (SOD). Also, various oxide layers may be used to form the device isolation layer at the same time.

When the wet strip process is performed by using the phosphoric acid (H₃PO₄), a difference in an effective field height (EFH) may occur due to the difference in selectivity of different isolation materials. Also, since the wet strip process has an isotropic property, bridges, for example, may be formed due to etching of sides of the device isolation layer. Furthermore, a cell region may widen from side to side due to the isotropic property of the wet strip process, and a peripheral region may also widen from side to side, and dishing phenomenon of the oxide layer may occur in the peripheral region.

When the wet strip process is performed, dip time using the phosphoric acid is relatively long and the dishing phenomenon may occur. Thus, dry cleaning equipment for lowering the height of the oxide layer thus formed is additionally required in order to control the EFH and adds costs for the overall process.

FIG. 1 is a transmission electron microscopic (TEM) photograph illustrating concerns in a conventional semiconductor device.

As shown in FIG. 1, a dishing phenomenon occurs on a spin on dielectric (SOD) layer that is relatively soft when a nitride hard mask is removed by a wet strip process. When the dishing phenomenon occurs, additional dry cleaning is performed in order to control an effective field height (EFH) and remove the dishing phenomenon, where such a step adds additional complexity to the overall process and a fabrication margin is compromised.

### SUMMARY OF THE INVENTION

Exemplary embodiments of the present invention are directed to a method for fabricating a semiconductor device which alleviates concerns in manufacturing that may arise when a nitride hard mask is removed by using a wet strip process.

In accordance with an embodiment of the present invention, a method for fabricating a semiconductor device includes forming a nitride pattern and a hard mask pattern over a substrate; forming a trench by etching the substrate using the hard mask pattern as an etch barrier; forming an oxide layer filling the trench; performing a planarization process on the oxide layer until the nitride pattern is exposed; and removing the nitride pattern though a dry strip process using a plasma.

The dry strip process may use a gas having an etch selectivity with respect to the oxide layer. The dry strip process may be performed by using a hydrofluorocarbon gas (CHₓF_{y}, where x and y are natural numbers). The dry strip process may be performed by using a mixture of the hydrofluorocarbon gas and tetrafluoromethane (CF₄), or a mixture of the hydrofluorocarbon gas and methane (CH₄). The hydrofluorocarbon gas may include at least one gas selected from a group consisting of fluoroform (CHF₃), difluoromethane (CH₂F₂) and fluoromethane (CH₃F).

The dry strip process may be performed by using a mixture of the hydrofluorocarbon gas and oxygen (O₂) gas. Here, the oxygen gas may have a flow amount ranging from approximately 20% to approximately 400% of a flow amount of the hydrofluorocarbon gas.

The method may further include removing the oxide layer to a certain depth, before the removing of the nitride pattern.

The removing of the nitride pattern may include removing the oxide layer to a certain depth simultaneously.

In accordance with another embodiment of the present invention, a method for fabricating a semiconductor device includes forming a nitride pattern and a hard mask pattern over a substrate; forming a first trench and a second trench by etching the substrate using the hard mask pattern as an etch barrier, wherein the second trench has a greater width than the first trench; forming an oxide layer filling the first and second trenches; performing a planarization process on the oxide layer until the nitride pattern is exposed; and removing the nitride pattern though a dry strip process using a plasma.

The first trench may be formed in a cell region, and the second trench may be formed in a peripheral region.

In accordance with another embodiment of the present invention, a method for fabricating a semiconductor device includes forming a nitride pattern and a hard mask pattern over a substrate; forming a trench by etching the substrate using the hard mask pattern as an etch barrier; forming an oxide layer filling the trench; performing a planarization process on the oxide layer until the nitride pattern is exposed; removing the oxide layer to a certain depth; and removing the nitride pattern though a dry strip process using a plasma after the oxide layer is removed to the certain depth.

The removing of the oxide layer may be performed by using a mixture of tetrafluoromethane (CF₄) gas and a hydrofluorocarbon gas (CHₓF_{y}, where x and y are natural numbers).

The dry strip process may be performed by using a mixture of a hydrofluorocarbon gas and methane (CH₄).

### BRIEF DESCRIPTION OF THE DRAWINGS

FIG. 1 is a transmission electron microscopic (TEM) photograph illustrating concerns in a conventional semiconductor device.

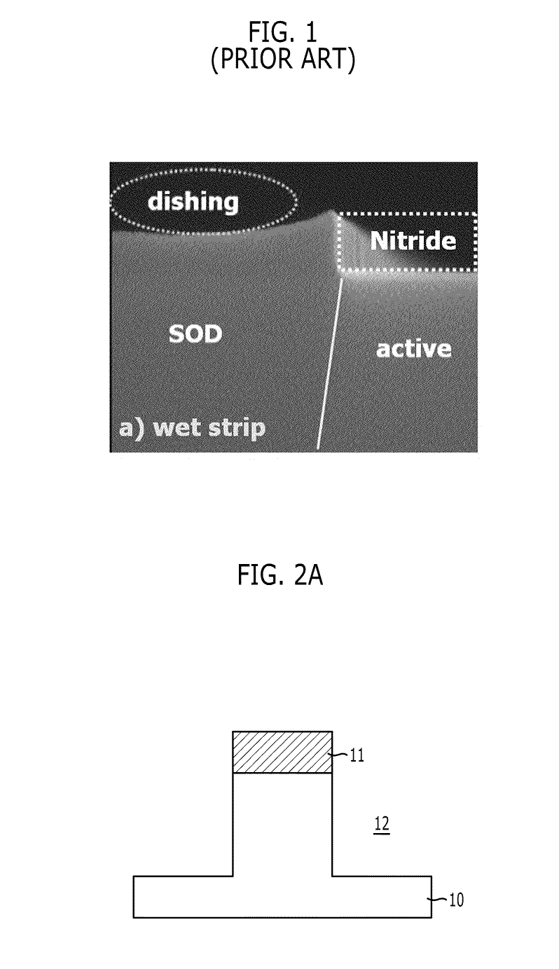

FIGS. 2A through 2C are cross-sectional views illustrating a method for fabricating a semiconductor device in accordance with a first embodiment of the present invention.

FIGS. 3A through 3C are cross-sectional views illustrating a method for fabricating a semiconductor device in accordance with a second embodiment of the present invention.

FIG. 4 is a transmission electron microscopic (TEM) photograph illustrating features of a device isolation layer in accordance with an embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

### First Embodiment

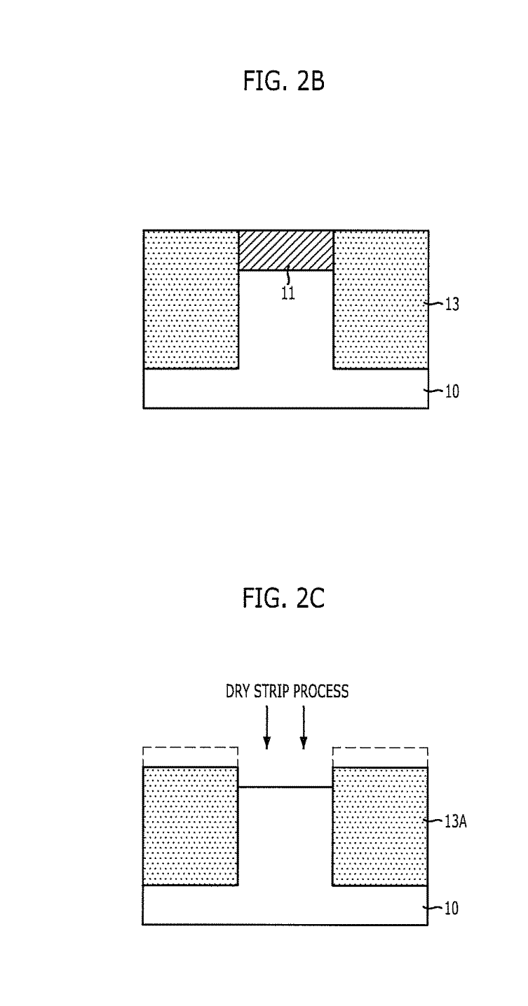

FIGS. 2A through 2C are cross-sectional views illustrating a method for fabricating a semiconductor device in accordance with a first embodiment of the present invention.

As shown in FIG. 2A, a nitride pattern 11 and a hard mask pattern (not shown) are formed over a substrate 10. The hard mask pattern is used to form a trench for device isolation. The nitride pattern 11 is formed as an etch stop layer when a subsequent device isolation layer is formed. Before the nitride pattern 11 is formed, a pad oxide layer (not shown) is formed over the substrate 10.

A trench 12 is formed by etching the substrate 10 using the hard mask pattern as an etch barrier.

As shown in FIG. 2B, a device isolation layer 13 is formed by filling the trench 12 with an oxide layer. The oxide layer includes at least one material selected from a group consisting of a spin on dielectric oxide layer, a boron phosphorus silicate glass (BPSG) oxide layer, a high density plasma (HDP) oxide layer, and a thermal oxide layer. When the device isolation layer 13 is formed, according to an example, at least two different kinds of oxide materials may be exposed as an upper surface.

In forming the device isolation layer 13, the oxide layer is formed to have a predetermined thickness sufficient to fill the trench 12, and a planarization process is performed on the oxide layer until the nitride pattern 11 is exposed. The planarization process includes a chemical mechanical polishing (CMP). The hard mask pattern (not shown) formed over the nitride pattern 11 is removed during the planarization process.

Before the oxide layer is filled in the trench 12, a wall oxide may be formed over the surface of the trench through a sidewall oxidation process, and a liner nitride may also be formed additionally before the oxide layer is filled in the trench 12.

As shown in FIG. 2C, the nitride pattern 11 is removed by performing a dry strip process using plasma. Since the dry strip process has little etch characteristic variation among different kinds of the oxide layers, uniform etch is made possible regardless of which kind of the oxide layer forms the device isolation layer 13.

According to an example, the dry strip process may use a gas having an etch selectivity with respect to the device isolation layer 13 in order to selectively remove the nitride pattern 11.

The dry strip process may be performed by using a plasma having a hydrofluorocarbon gas, i.e., CHₓF_{y}, where x and y are natural numbers. For example, the hydrofluorocarbon gas may include at least one gas selected from a group consisting of fluoroform (CHF₃), difluoromethane (CH₂F₂) and fluoromethane (CH₃F). Also, tetrafluoromethane (CF₄) or methane (CH₄) may be added to the hydrofluorocarbon gas in performing the dry strip process. An etch selectivity between the device isolation layer 13 and the nitride pattern 11 may be controlled by different combinations of the hydrofluorocarbon gas.

In order to increase the etch selectivity of the nitride pattern 11 with respect to the device isolation layer 13, oxygen (O₂) gas may be added when the dry strip process is being performed. When the O₂ gas is added, polymer may be easily removed, and thus an etch rate of the nitride pattern 11 is increased. Thus, the etch selectivity of the nitride pattern 11 with respect to the device isolation layer 13 is increased. According to different kinds of the hydrofluorocarbon gas, the flow amount of the O₂ gas used in the dry strip process ranges from approximately 20% to approximately 400% of the flow amount of the hydrofluorocarbon gas.

When the nitride pattern 11 is removed by performing a dry strip process using the plasma as described above, the dishing phenomenon of the device isolation layer 13 due to the wet strip process may be prevented/reduced. Also, the overall time for performing the dry strip process becomes shorter than that of the wet strip process, and the fabrication margin may be ensured.

In case of the dry strip process, it is easier to acquire an anisotropic property than in the wet strip process, so that etching of sides of the device isolation layer 13 may be prevented/reduced. In order to ensure such an anisotropic property during the dry strip process, a bias power greater than a source power is applied. For example, the bias power may be at least 100 W, where the bias power may range from approximately 100 W to approximately 1000 W. The source power ranges from approximately 0 W to approximately 1000 W.

By controlling the etch selectivity between the nitride pattern 11 and the device isolation layer 13 during the dry strip process, the nitride pattern 11 is selectively removed. When the nitride pattern 11 is removed, the device isolation layer 13 may be simultaneously removed to a certain depth. Therefore, a subsequent height adjustment process of the device isolation layer 13 to control an effective field height (EFH) of the device isolation layer 13 may be avoided. Thus, a sufficient fabrication margin may also be provided.

On the other hand, before the nitride pattern 11 is removed, the device isolation layer 13 may be removed to a certain depth. Although the device isolation layer 13 is removed to a certain depth before the nitride pattern 11 is removed, the fabrication margin may be secured because both of the removal processes are performed in-situ in the same chamber. When the wet strip process is performed, the subsequent EFH control process of the device isolation layer 13 is performed ex-situ in different chambers. Here, in the dry strip process, the partial removal of the device isolation layer 13 is performed using a mixture of the hydrofluorocarbon gas and CF₄ gas, and the removal of the nitride pattern 11 is performed using a mixture of the hydrofluorocarbon gas and CH₄ gas.

A reference numeral 13A represents an etched device isolation layer, where the device isolation layer 13 is removed to a certain depth in order to control the EFH.

### Second Embodiment

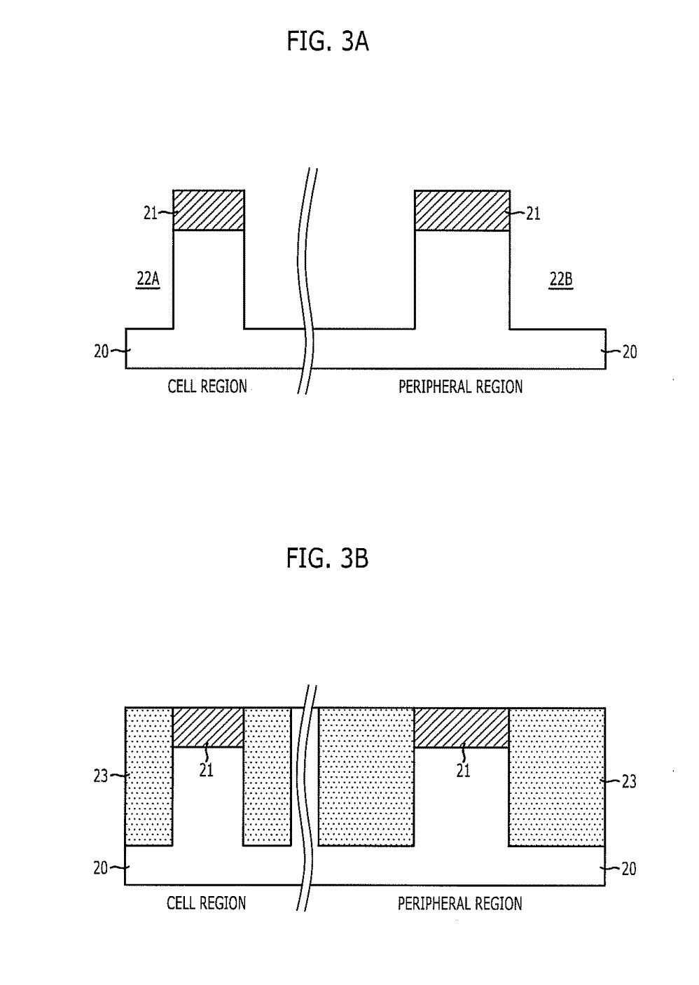

FIGS. 3A through 3C are cross-sectional views illustrating a method for fabricating a semiconductor device in accordance with a second embodiment of the present invention.

As shown in FIG. 3A, a nitride pattern 21 and a hard mask pattern (not shown) are formed over a substrate 20 having a cell region and a peripheral region. The hard mask pattern is used to form trenches 22A and 22B for device isolation. The nitride pattern 21 is formed as an etch stop layer when a subsequent device isolation layer is formed. Before the nitride pattern 21 is formed, a pad oxide layer (not shown) is formed over the substrate 20.

A first trench 22A and a second trench 22B are formed by etching the substrate 20 using the hard mask pattern as an etch barrier. Size and density of the pattern in the cell region are different from those of the peripheral region, where their respective trenches have different widths. For example, the first trench 22A is formed in the cell region, and the second trench 22B having a greater width than the first trench 22A is formed in the peripheral region.

As shown in FIG. 3B, a device isolation layer 23 is formed by filling the first trench 22A and the second trench 22B with an oxide layer. The oxide layer includes at least one material selected from a group consisting of a spin on dielectric oxide layer, a boron phosphorus silicate glass (BPSG) oxide layer, a high density plasma (HDP) oxide layer, and a thermal oxide layer. When the device isolation layer 23 is formed, according to an example, at least two different kinds of oxide materials may be exposed as an upper surface.

In forming the device isolation layer 23, the oxide layer is formed to have a predetermined thickness sufficient to fill the trench 22, and a planarization process is performed on the oxide layer until the nitride pattern 21 is exposed. The planarization process includes a chemical mechanical polishing (CMP). The hard mask pattern (not shown) formed over the nitride pattern 21 is removed during the planarization process.

Before the oxide layer is filled in the trench 22A or 22B, a wall oxide may be formed over the surface of the trench through a sidewall oxidation process, and a liner nitride may also be formed additionally before the oxide layer is filled in the trench.

As shown in FIG. 3C, the nitride pattern 21 is removed by performing a dry strip process using plasma. Since the dry strip process has little etch characteristic variation among different kinds of the oxide layers, uniform etch is made possible regardless of which kind of the oxide layer forms the device isolation layer 23.

According to an example, the dry strip process may use a gas having an etch selectivity with respect to the device isolation layer 23 in order to selectively remove the nitride pattern 21.

The dry strip process may be performed by using a plasma having a hydrofluorocarbon gas, i.e., CHₓF_{y}, where x and y are natural numbers. For example, the hydrofluorocarbon gas may include at least one gas selected from a group consisting of fluoroform (CHF₃), difluoromethane (CH₂F₂) and fluoromethane (CH₃F). Also, tetrafluoromethane (CF₄) or methane (CH₄) may be added to the hydrofluorocarbon gas in performing the dry strip process. An etch selectivity between the device isolation layer 23 and the nitride pattern 21 may be controlled by different combinations of the hydrofluorocarbon gas.

In order to increase the etch selectivity of the nitride pattern 21 with respect to the device isolation layer 23, oxygen (O₂) gas may be added when the dry strip process is being performed. When the O₂ gas is added, polymer may be easily removed, and thus an etch rate of the nitride pattern 21 is increased. Thus, the etch selectivity of the nitride pattern 21 with respect to the device isolation layer 23 is increased. The flow amount of the O₂ gas used in the dry strip process ranges from approximately 20% to approximately 400% of the flow amount of the hydrofluorocarbon gas according to the kinds of the hydrofluorocarbon gas.

When the nitride pattern 21 is removed by performing the dry strip process using the plasma as described above, the dishing phenomenon of the device isolation layer 23 due to the wet strip process may be prevented/reduced. Also, the overall time for performing the dry strip process becomes shorter than that of the wet strip process, and the fabrication margin may be secured.

In case of the dry strip process, it is easier to acquire an anisotropic property than in the wet strip process, so that etching of sides of the device isolation layer 23 may be prevented/reduced. In order to ensure such an anisotropic property during the dry strip process, a bias power greater than a source power is applied. For example, the bias power may be at least 100 W, where the bias power may range from approximately 100 W to approximately 1000 W. The source power ranges from approximately 0 W to approximately 1000 W.

In addition, when the wet strip process is performed, two-step strip process is performed for the cell region and the peripheral region separately due to the difference in etch rates that result from different pattern densities. However, since the difference in etch rates due to the pattern density difference is insignificant in case of the dry strip process, one-step strip process may be performed to remove the nitride pattern 21 in the cell region and the peripheral region simultaneously. Therefore, additional mask forming process, strip process and mask removing process for performing the two-strip process may be avoided in the dry strip process.

By controlling the etch selectivity between the nitride pattern 21 and the device isolation layer 23 during the dry strip process, the nitride pattern 21 is selectively removed. When the nitride pattern 21 is removed, the device isolation layer 23 may be simultaneously removed to a certain depth. Therefore, a subsequent height adjustment process of the device isolation layer 23 to control an effective field height (EFH) of the device isolation layer 23 may be avoided. Thus, a sufficient fabrication margin may also be provided.

On the other hand, before the nitride pattern 21 is removed, the device isolation layer 23 may be removed to a certain depth. Although the device isolation layer 23 is removed to a certain depth before the nitride pattern 21 is removed, the fabrication margin may be secured because both of the removal processes are performed in-situ in the same chamber. When the wet strip process is performed, the subsequent EFH control process of the device isolation layer 23 is performed ex-situ in different chambers. Here, in the dry strip process, the partial removal of the device isolation layer 23 is performed using a mixture of the hydrofluorocarbon gas and CF₄ gas, and the removal of the nitride pattern 21 is performed using a mixture of the hydrofluorocarbon gas and CH₄ gas.

A reference numeral 23A represents an etched device isolation layer, where the device isolation layer 23 to a certain depth is removed in order to control the EFH.

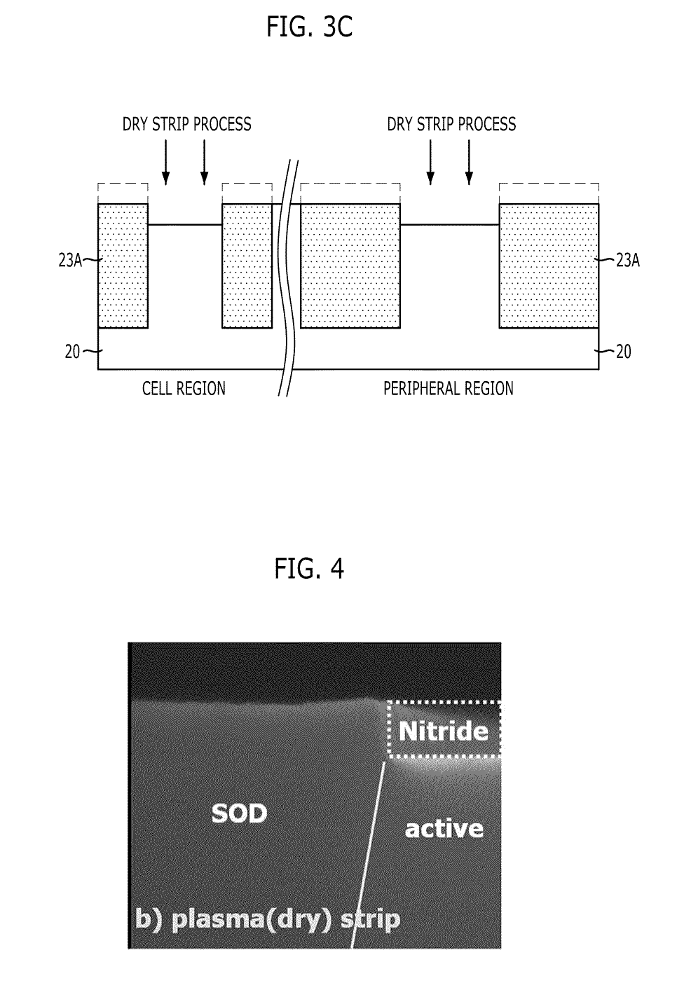

FIG. 4 is a transmission electron microscopic (TEM) photograph illustrating features of a device isolation layer in accordance with an embodiment of the present invention.

As shown in FIG. 4, a device isolation layer (SOD) has a flat surface when a dry strip process using plasma is performed to remove a nitride pattern.

According to an embodiment of the present invention, a nitride pattern for forming a device isolation layer is removed by performing a dry strip process using plasma, and thus, dishing phenomenon of the device isolation layer may be prevented/reduced. Therefore, the sufficient fabrication margin may be secured.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a nitride pattern and a hard mask pattern over a substrate;
forming a trench by etching the substrate using the hard mask pattern as an etch barrier;
forming an oxide layer filling the trench;
performing a planarization process on the oxide layer until the nitride pattern is exposed; and
removing the nitride pattern though a dry strip process using a plasma.

2. The method of claim 1, wherein the dry strip process uses a gas having an etch selectivity with respect to the oxide layer.

3. The method of claim 1, wherein the dry strip process is performed by using a hydrofluorocarbon gas (CHₓF_{y}, where x and y are natural numbers).

4. The method of claim 3, wherein the dry strip process is performed by using a mixture of the hydrofluorocarbon gas and tetrafluoromethane (CF₄), or a mixture of the hydrofluorocarbon gas and methane (CH₄).

5. The method of claim 3, wherein the hydrofluorocarbon gas includes at least one gas selected from a group consisting of fluoroform (CHF₃), difluoromethane (CH₂F₂) and fluoromethane (CH₃F).

6. The method of claim 1, wherein the dry strip process is performed by using a mixture of the hydrofluorocarbon gas and oxygen (O₂) gas.

7. The method of claim 6, wherein the oxygen gas has a flow amount ranging from approximately 20% to approximately 400% of a flow amount of the hydrofluorocarbon gas.

8. The method of claim 1, further comprising:
removing the oxide layer to a certain depth before the removing of the nitride pattern.

9. The method of claim 1, wherein the removing of the nitride pattern includes:
removing the oxide layer to a certain depth simultaneously.

10. A method for fabricating a semiconductor device, comprising:
forming a nitride pattern and a hard mask pattern over a substrate;
forming a first trench and a second trench by etching the substrate using the hard mask pattern as an etch barrier, wherein the second trench has a greater width than the first trench;
forming an oxide layer filling the first and second trenches;
performing a planarization process on the oxide layer until the nitride pattern is exposed; and
removing the nitride pattern though a dry strip process using a plasma.

11. The method of claim 10, wherein the dry strip process uses a gas having an etch selectivity with respect to the oxide layer.

12. The method of claim 10, wherein the dry strip process is performed by using a hydrofluorocarbon gas (CHₓF_{y}, where x and y are natural numbers).

13. The method of claim 12, wherein the dry strip process is performed by using a mixture of the hydrofluorocarbon gas and tetrafluoromethane (CF₄), or a mixture of the hydrofluorocarbon gas and methane (CH₄).

14. The method of claim 12, wherein the hydrofluorocarbon gas includes at least one gas selected from a group consisting of fluoroform (CHF₃), difluoromethane (CH₂F₂) and fluoromethane (CH₃F).

15. The method of claim 10, wherein the dry strip process is performed by using a hydrofluorocarbon gas and oxygen gas (O₂).

16. The method of claim 15, wherein the oxygen gas has a flow amount ranging from approximately 20% to approximately 400% of a flow amount of the hydrofluorocarbon gas.

17. The method of claim 10, further comprising:
removing the oxide layer to a certain depth, before the removing of the nitride pattern.

18. The method of claim 10, wherein the removing of the nitride pattern includes:
removing the oxide layer to a certain depth simultaneously.

19. The method of claim 10, wherein the first trench is formed in a cell region, and the second trench is formed in a peripheral region.

20. A method for fabricating a semiconductor device, comprising:
forming a nitride pattern and a hard mask pattern over a substrate;
forming a trench by etching the substrate using the hard mask pattern as an etch barrier;
forming an oxide layer filling the trench;
performing a planarization process on the oxide layer until the nitride pattern is exposed;
removing the oxide layer to a certain depth; and
removing the nitride pattern though a dry strip process using a plasma after the oxide layer is removed to the certain depth.

21. The method of claim 20, wherein the removing of the oxide layer is performed by using a mixture of tetrafluoromethane (CF₄) gas and a hydrofluorocarbon gas (CHₓF_{y}, where x and y are natural numbers).

22. The method of claim 20, wherein the dry strip process uses a gas having an etch selectivity with respect to the oxide layer.

23. The method of claim 20, wherein the dry strip process is performed by using a hydrofluorocarbon gas (CHₓF_{y}, where x and y are natural numbers).

24. The method of claim 23, wherein the hydrofluorocarbon gas includes at least one gas selected from a group consisting of fluoroform (CHF₃), difluoromethane (CH₂F₂) and fluoromethane (CH₃F).

25. The method of claim 20, wherein the dry strip process is performed by using a mixture of a hydrofluorocarbon gas and methane (CH₄).

26. The method of claim 20, wherein the dry strip process is performed by using a mixture of a hydrofluorocarbon gas and oxygen (O₂) gas.

27. The method of claim 26, wherein the oxygen gas has a flow amount ranging from approximately 20% to approximately 400% of a flow amount of the hydrofluorocarbon gas.
